(19) United States
(12) Patent Application Publication
(10) Pub. No.: US 2024/0124667 A1
(43) Pub. Date: Apr. 18, 2024

(54) Multifunctional Carbon Nanotubes-Glass Fiber-Epoxy Composites with High Density Interfaces for Microwave Absorption and Structural Materials

(71) Applicants: Guang-lin Zhao, Baton Rouge, LA (US); Rong Zhao, Huaibel in Anhui province (CN)

(72) Inventors: Guang-lin Zhao, Baton Rouge, LA (US); Rong Zhao, Huaibel in Anhui province (CN)

(73) Assignee: Southern University and A&M College, (omitted)

(21) Appl. No.: 17/965,722

(22) Filed: Oct. 13, 2022

(51) Int. Cl. C08J 5/24; B29B 7/22; B29B 7/88; B29C 70/00; B29C 70/08; B29C 70/22; B29C 70/30; C08K 3/04; H05K 9/00

(52) U.S. Cl. CPC C08J 5/249; B29B 7/22; B29B 7/88; B29C 70/003; B29C 70/081; B29C 70/22; B29C 70/30; C08J 5/244; C08K 3/041; H05K 9/009; B82Y 30/00; C08J 2363/00; C08K 2201/003; C08K 2201/004; C08K 2201/011

(57) ABSTRACT

A process for forming multifunctional carbon nanotubes-glass fiber-epoxy composites with high density interfaces for microwave absorption and structural materials application useful as a multifunctional microwave absorption and low-weight structural material without a need of additional coating.

### STATEMENT OF GOVERNMENT INTEREST

This invention was funded in part by the National Science Foundation (NSF) CREST project (award no. HRD 1736136), the Army Research Office (ARO) (award no. W911NF-15-1-0483), and the Office of Naval Research (ONR) (award no. N00014-22-1-2744) in the United States.

### FIELD OF THE INVENTION

This invention generally relates to a process for forming multifunctional carbon nanotubes-glass fiber-epoxy composites with high density interfaces for microwave absorption and structural materials applications.

### BACKGROUND OF THE INVENTION

Advanced microwave absorption materials based on polymer nano-composites can be used in modern technologies to protect sensitive circuits, electronic devices, electromagnetic interference (EMI) shielding, and aircrafts, as well as for human exposure mitigation such as in cellular phones. An important factor for the designer of electromagnetic (EM) wave absorption materials is the absorption efficiency with respect to weight. Therefore, a composite consisting of non-corrosive, lightweight polymer and nano-scale particles has an absolute advantage. Carbon nanotubes (CNTs) and graphene nanoplatelets (GNPs) meet this criterion. CNTs and GNPs polymer composites present a remarkable EM wave absorption performance.

In previous research and applications, microwave absorption materials were mainly used as a coating over existent structures such as aircrafts. However, the coating increases the weight of the structures. The mechanical properties of coating is typically not a major concerning since the mechanical strength is provided by the underlying structure frame.

With the rapid arising of wireless technology and other applications towards gigahertz frequency in modern communications, microwave absorbing materials (MAM) are playing an increasingly significant role in healthcare, electronic reliability, and defense security. The mutual electromagnetic (EM) interferences among electronic gadgets, process equipment, measuring instruments, high security devices and others can lead to a disturbance or breakdown of normal operation of appliances. Therefore, to reduce the unwanted EM radiations, some EM shielding mechanisms must be provided to ensure an undisturbed functioning of devices even in the presence of external EM noises. Electromagnetic interference (EMI) shields essentially prevent the EM wave emissions from an outside source to deteriorate the electronic performances of the devices. Generally, metals have been employed as effective shielding materials because of their low EM wave transmission. However, metals have high EM wave reflection and low EM absorption, external EM noises or EMI still occur in the surrounding environment.

For some other applications, low EM wave reflection or high reflection loss (RL) materials are essential for the security of the devices. In order to achieve a high RL, a low transmission is also needed; otherwise, EM noise transmits through the material and EMI still remains. Therefore, a material, which possesses the properties of low reflection (or high RL), low transmission (or high transmission loss/high EMI shielding) and high absorption of EM noises, is desirable. That is still challenging to achieve in the research field. Hence, there is a continuous effort to improve EM wave absorption material to attain better microwave absorption performance.

Many materials have been used for microwave absorption, which include magnetic and dielectric (non-magnetic) absorbers. A desired microwave absorption material is expected to be environmentally benign, light-weight, long-term durability, resistant to corrosion, and flexible to processing. The traditional microwave absorption materials cannot meet all these requirements at the same time. For these reasons, carbon-based nanomaterials are advantageous to material scientists in their ongoing efforts to design new microwave absorption materials and radar absorbing structures.

Recently, composites based on carbon nanotubes (CNTs) in polymer matrices are widely explored for applications due to their unique structures and EM properties. Besides, it is known that the electrical and thermal properties of composites strongly depend on the dispersion state of CNTs in polymer matrix. Research studies showed that the mechanical properties of CNT/epoxy composite can also be affected by the content of CNTs, the dispersions of CNTs in resin matrix, and the existence of high amount of agglomerated CNT particles.

Several studies have reported CNT polymer composites with high and low loadings of CNTs in various matrices. Kim and collaborators designed and studied several CNTs based polymer nanocomposites for radar absorbing structures. Lee et al. studied the nanocomposites as radar absorbing structure using the optimum design method with the dispersion of carbonaceous nano-conductive particles. Bhattacharya et al. studied the graphene and CNTs based bi-functional polymer nanocomposites, and showed high reflection loss in the frequency range of 8.2-12.3 GHz, along with some other qualities such as light-weight, thin, thermal and chemical stability; nonetheless, the microwave transmission properties of the composites were not included. Jyoti et al. studied the mechanical and electrical properties of multi-walled carbon nanotube (MWCNT) reinforced acrylonitrile butadiene styrene (ABS). Their results showed that incorporation of 3 wt % MWCNTs in ABS lead to 29% enhancement (up to 69.4 MPa) in the tensile strength over pure ABS (53.5 MPa), and the composite also showed high EMI shielding effectiveness (SE) with 7 and 10 wt % MWCNTs in ABS, attributed to the reflection of the EM radiation; notwithstanding, the data of reflection properties were not included.

Previously, most microwave absorption materials were designed and used as a coating over existing structures (such as for anechoic chamber, aircraft, and others), that in turn increased the weight of the structures. The mechanical properties of the coating were not a major concern since the mechanical strength of the subject was mainly provided by the structural materials. In this work, we aim to explore multifunctional polymer nanocomposites, which can be used for microwave absorption and also as structural materials. So that, a separate coating on the application structures would not be needed if multifunctional polymer nanocomposites could be realized. In addition, the microwave wave absorption of the composite can be enhanced by taking the advantages of large thickness of structural materials.

Previous studies showed that the mechanical properties of polymer composites can be highly enhanced by the addition of fibers (glass fiber, carbon fiber, etc.) to the polymer matrix. Suitable compositions and orientation of fibers made desired mechanical properties of the composites comparable to structural materials such as aluminum alloys with much lower specific gravity. Glass fiber (GF) reinforced epoxy composites are increasingly used in commercial and aerospace applications, replacing some metallic materials due to their high mechanical strength, high flexural modulus, high chemical resistance, and low expansion rate.

### BRIEF SUMMARY OF THE INVENTION

The present invention is a multifunctional carbon nanotubes-glass fiber-epoxy composites with high density interfaces for microwave absorption and structural materials applications composites, which can be used for microwave absorption and also as part of structural materials. The present invention provides a material structure so that a separate coating on the application structures would not be needed, when multifunctional polymer nano composites could be used. The developed multifunctional polymer nano-composites is light weight and mechanically strong. Strong EM wave absorption is realized and tuned to wide band frequencies by taking the advantages of large thickness of structural materials. As we demonstrated, the multifunctional nano composites have very strong mechanical properties, light weight, high density interfaces, and remarkable microwave absorption.

### EXEMPLARY FIGURES

FIG. 1 is a schematic view for MWCNT-GF-epoxy composite fabrication by a hand laying-up process.

FIGS. 2(a)-(d) depict exemplary SEM surface morphologies of (a) neat epoxy-GF, (b) 1.4 wt % MWCNTs loading, (c) 3.1 wt % MWCNTs loading, and (d) 5.0 wt % MWCNTs loading in MWCNT-GF-epoxy composites.

FIGS. 3(a)-(f) depict exemplary SEM cross-section morphologies of the MWCNT-GF-Epoxy composites with (a) and (d) 6 plies GF (55 wt %), (b) and (e) 8 plies GF (67 wt %), (c) and (f) 10 plies GF (74 wt %).

FIGS. 4(a)-(d) are exemplary depictions of (a) The weight percentages of GFs in composites with different GF plies in the composites; (b) The density of the composites for various GF loadings; (c) Stress-strain curves; and (d) tensile strength (with error bar) of the composites with various GF loadings.

FIG. 5 depict exemplary DC conductivities of MWCNT-GF-epoxy composites with various MWCNT loadings with the inset plot represents the linear form of the power law.

FIGS. 6(a)-(d) are exemplary depictions of (a) The microwave reflection loss, (b) absorption ratio, (c) transmission loss, and (d) permittivity value of MWCNT-GF-epoxy composites with different MWCNT loadings in wt %.

FIGS. 7(a)-(d) are exemplary depictions of (a) The microwave reflection loss, (b) absorption ratio, (c) transmission loss, and (d) permittivity value of MWCNT-GF-epoxy composites with different GF contents and 5 wt % MWCNTs in epoxy resin.

FIGS. 8(a)-(d) are exemplary depictions of (a) The microwave reflection loss, (b) absorption ratio, (c) transmission loss, and (d) permittivity value of MWCNT-GF-epoxy composites with different GF contents and 9 wt % MWCNTs in epoxy resin.

Figures S1(a)-(b) depict (a) The stress-strain curves obtained from the tensile tests and (b) column chart of the tensile strength for the composites with various loadings of MWCNTs, the GF content in the composites was maintained at 55 wt %.

Figure S2 depicts the microwave absorption ratio of GF reinforced epoxy composites without MWCNT loading.

Figures S3(a)-(d) depict (a) the microwave reflection loss, (b) absorption ratio, (c) transmission loss, and (d) permittivity value of MWCNT-GF-epoxy composites with different GF contents and 7 wt % MWCNTs in epoxy resin.

Figure S4(a)-(c) depicts SEM cross-section morphologies of the MWCNT-GF-Epoxy composites (a) 6L9, (b) 8L9, and (c) 10L9.

Figure S5(a)-(d) depicts (a) The microwave reflection loss, (b) absorption ratio, (c) transmission loss, and (d) permittivity value of MWCNT-GF-epoxy composites with different GF contents and 11 wt % MWCNTs in epoxy resin.

### DETAILED DESCRIPTION OF THE INVENTION

Therefore, in this work, we reinforced microwave absorption MWCNT-epoxy composite using GFs. However, the addition of GFs in the composite reduced the MWCNT loading capacity. Hence, a systematic investigation of the mechanical and EM wave absorption properties of MWCNT-GF-epoxy composites is much needed. We studied the dispersion properties of MWCNTs and GFs in epoxy resin, mechanical properties, electrical conductivity, and microwave absorption of the materials. These composites showed good microwave absorption properties along with highly improved tensile strength that is comparable to commercial aluminum alloy 6061. The mass densities of the composites were about 1.5-1.8 g·cm⁻³ that is lighter than aluminum alloy 6061, which has a mass density of about 2.7 g·cm⁻³. With relatively high loadings of MWCNTs and GFs, the composites showed some peculiar microwave absorption property dependence, contradicting to the conventional wisdom, due to high density interfaces in the composites.

### Materials and Methods

### Materials and Sample Preparation

In this exemplary study, we used high purity MWCNTs (>95%) with outer diameters <8 nm and lengths between 10-30 μm from CheapTubes Inc. Commercial GFs (satin weave fabrics 7781E), epoxy resin (#300) and hardener (#21) were purchased from Fibre Glast Developments Corp and Aero Marine Products, respectively.

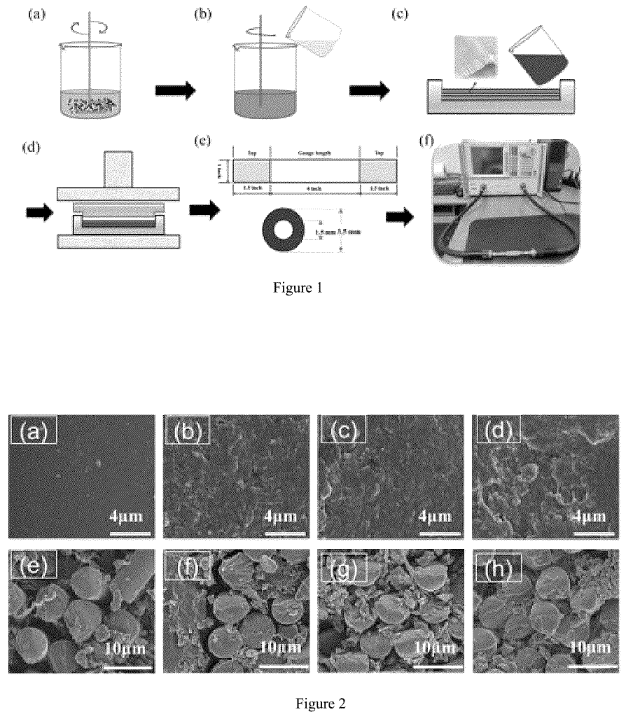

The wet hand laying-up process was used for the composite preparation as illustrated in FIG. 1. FIG. 1 depicts an exemplary schematic view for MWCNT-GF-epoxy composite fabrication by a hand laying-up process. It should be noted that although the invention is described with respect to the hand laying up process, other laying up processes are contemplated, such as, machine laying up process. The GF cloth was cut into 9×9 inch squire pieces for fitting a square steel mold. The Teflon non-stick dry film lubricant was sprayed onto the steel mold before the fabrication, which would aid the removal of the composites from the steel mold with flat surface. MWCNTs were weighed and added to epoxy resin (Aero Marine #300) at various concentrations (1, 3, 5, 7, 9, and 11 wt %). Due to the agglomeration tendency of MWCNTs, epoxy resin with MWCNTs was stirred for about 17 hours using shear-mixing method with an overhead stirrer (Scilogex OS20-S) at the speed of 100 revolutions per minute (rpm) (FIG. 1(a)).

Subsequently, Aero Marine hardener #21 was slowly poured into the mixture to avoid introducing air bubbles and stirred slowly for about 15 minutes to mix well (FIG. 1(b)). The well-mixed MWCNT-epoxy solution was loaded into the mold with various plies of GF (FIGS. 1(c) and (d)) using hand laying up method. That resulted in different fiber and MWCNT contents in the composites. The mold with the sample was then cured at 50° C. for about 24 hours and the MWCNT-GF-epoxy composite samples were taken out from the steel mold. Finally, post-cure was made for about 48 hours at 80° C. The GF contents and MWCNT loadings in weight percentage related to the total weight of MWCNT-GF-epoxy composites were calculated and listed in Table S1 in the Supporting Information.

### Characterization Setups

The studies for the morphology and dispersion of the composites were carried out using a scanning electron microscope (SEM) (model JSM-6610LV (JOEL. Japan)). The MWCNT-GF-epoxy composites were cut to small pieces (5 mm×2 mm) for surface and cross-section images. For tensile strength measurements, rectangular shaped tensile specimens (7 inches×1 inch as shown in FIG. 1 (e)) were sized according to ASTM D3039 standards. GF-epoxy laminate tabs were bonded at the ends of the specimens for tensile strength measurement. The in-plane tensile properties of polymer composites were measured at room temperature by using Material Testing System (MTS) machine (QTEST 150). The electrical conductivity of the composites was measured by using a high resistance tester (ZC36, Shanghai Abeat Technology Co., Ltd, China). Each sample was tested at least five times for better accuracy. The EM wave absorption properties were studied by measuring the scattering parameters (S-parameters) of the samples, using an Agilent Network Analyzer N5230C PNA-L and a coaxial transmission line method in the frequency range from 4 to 26.5 GHz (see FIG. 1 (f)). The samples were cut into an O-ring like shape for measurement with outer and inner diameters of 3.5 mm and 1.5 mm, respectively (FIG. 1 (e) bottom).

### Results and Discussion

### SEM Morphologic Studies

The SEM surface morphologies and cross-section images for the MWCNT-GF-epoxy composites with various loadings of MWCNT are exhibited in FIG. 2, where the weight content of GF in these composites was fixed to 55 wt %. Note that the same magnification was used for different samples to facilitate direct comparisons. It is observed that the surface of the specimen without MWCNT loading (FIG. 2 (a)) presents a flat and smooth morphology. With 1.4 wt % of MWCNT nanofillers in the composites, some rough surface grains appear over the sample surface (see FIG. 2 (b)). This deformation effect is attributed to the increased viscosity of the MWCNT-epoxy solution. As the MWCNT loading increased, some slippery short sheets and lines are formed (see FIGS. 2 (c) and (d)). The surface average roughness Rₐ for neat epoxy-GF, 1.4 wt %, 3.1 wt %, and 5.0 wt % MWCNT-epoxy-GF composites were 3.85 μm, 11.57 μm, 14.68 μm, and 18.14 μm, respectively.

In comparison, in previous research work, the MWCNTs-epoxy solutions were obtained by using a hotplate magnetic stirrer for 1 h. The SEM images for the morphologies of MWCNT-epoxy composites showed some string-like subjects on the samples that were attributed to MWCNT aggregates and MWCNT bundles in epoxy matrix. In this work, however, the morphologies of neat epoxy-GF and MWCNT-GF-epoxy lumps with the various MWCNT loadings did not show much difference from the surface and cross-section morphology images; in addition, the string-like subjects were not observed on the samples of this work, as shown in FIG. 2. That indicated a more uniform distribution of MWCNTs in epoxy resin than that in the previous work.

With reference to FIG. 2, exemplary SEM surface morphologies of (a) neat epoxy-GF, (b) 1.4 wt % MWCNTs loading, (c) 3.1 wt % MWCNTs loading, and (d) 5.0 wt % MWCNTs loading in MWCNT-GF-epoxy composites. The cross-section morphologies are: (e) neat epoxy-GF, (f) 1.4 wt % MWCNTs loading, (g) 3.1 wt % MWCNTs loading, and (h) 5.0 wt % MWCNTs loading in MWCNT-GF-epoxy composites are shown. The cross-section images (FIG. 2 (e)-(h)) present the transverse and longitudinal distributions of GFs in composites. FIG. 2 shows exemplary SEM surface morphologies of (a) neat epoxy-GF, (b) 1.4 wt % MWCNTs loading, (c) 3.1 wt % MWCNTs loading, and (d) 5.0 wt % MWCNTs loading in MWCNT-GF-epoxy composites. The cross-section morphologies are: (e) neat epoxy-GF, (f) 1.4 wt % MWCNTs loading, (g) 3.1 wt % MWCNTs loading, and (h) 5.0 wt % MWCNTs loading in MWCNT-GF-epoxy composites.

It is clearly shown that the epoxy-GF composite without MWCNT loading in FIG. 2 (e) exhibits some interface debond which could due to the mechanical cutting during the preparation for SEM measurement. FIGS. 2 (f) and (h) show improved fiber and epoxy interfacial bonding with MWCNT fillers in the composites. Due to the loading of MWCNTs to the epoxy resin, the MWCNT-epoxy bonding and disorder may lead to the deformation and the improved bonding between epoxy and GF.

As one of the most significant defects in fiber reinforced polymer composites, voids have considerable effect on a wide range of composite properties. Voids were mainly formed by mechanical air entrapment during resin flow. The process of mixing MWCNTs with epoxy resin could also cause air entrapment. The other possible reason for voids could be due to the inhomogeneous fiber architecture, resulting in non-uniform permeability of the fiber preform, which could cause local variation in resin velocity. In this work, low mechanical stirring was used to avoid introducing air bubbles in MWCNTs-epoxy solution. In addition, we implemented a press molding (press forces up to 700 N·cm⁻²) during the curing process of the composite samples, aiming to reduce voids in the material.

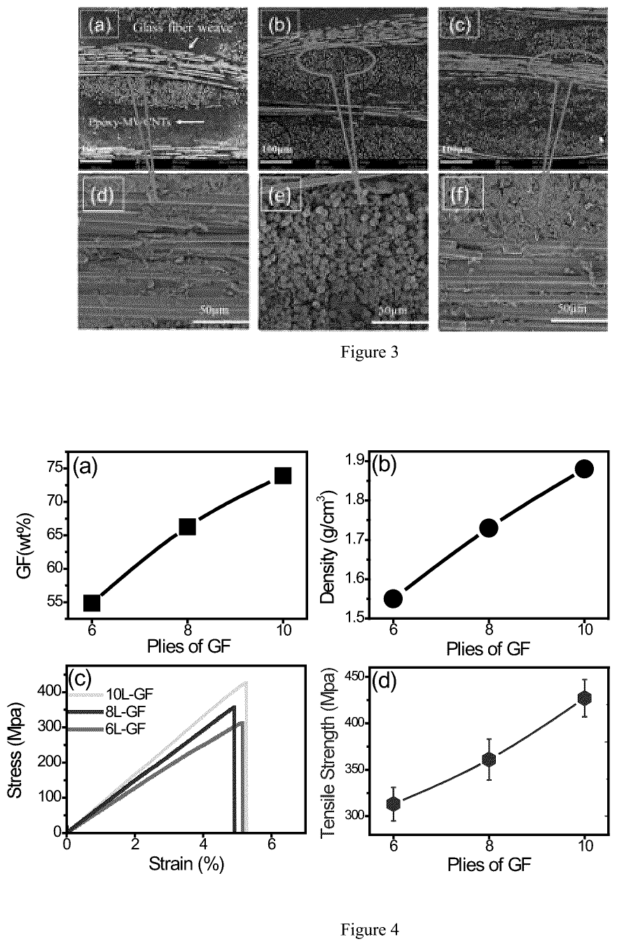

In this work, we also studied the property changes of the composites with different GF and MWCNT contents. In 2 mm thickness of the composites, we employed 6, 8, and 10 plies of satin weave 7781E fabrics (Fibre Glast Corp) that correspond to 55, 67, 74 wt % of GF loading ratios in the composites. FIG. 3 shows the SEM cross-sectional views of the composites with various GF contents. As can be seen FIG. 3 depicts exemplary SEM cross-section morphologies of the MWCNT-GF-Epoxy composites with (a) and (d) 6 plies GF (55 wt %), (b) and (e) 8 plies GF (67 wt %), (c) and (f) 10 plies GF (74 wt %). The MWCNT loadings were fixed to 5 wt % in epoxy resin. The images show the laying-up placements of GFs in the samples. The orientations of the GFs are shown at 0°/90° and distributed throughout the epoxy resin at different contents (55, 67, 74 wt %). The MWCNT-epoxy solution was wetted into and between GF plies. It shows sequential layers of GF adhered by MWCNT-epoxy solution.

The spaces between the plies of GFs are clearly shown in FIG. 3 (a), while barely seen in FIG. 3 (c) as the content of GFs increased to 74 wt %. As we discuss in the next sections, the epoxy resin with 5 wt % MWCNTs possesses relatively high electric conductivity and GFs are electric insulators. So the interfaces between MWCNT-epoxy and GFs could impact the microwave absorption properties of the composites. FIG. 3 (d)-(f) present the SEM images of selected sections of Figure (a)-(c) with higher resolution, aiming to show the interfaces between MWCNT-epoxy and GFs. As the GF loading increases in the composite, the density of the interfaces between MWCNT-epoxy and GFs also increases. More detailed discussions for the effect of the high-density interfaces on the mechanical and microwave absorption properties of the composites will be presented in the following sections.

### Mechanical Properties

The mechanical behavior of a fiber-reinforced composite with a fixed thickness highly depends on the fiber strength and modulus, the chemical stability, matrix strength, and the fibers laid or laminated in the matrix during the preparation of the composite. The hierarchical fibers in laminated composite structure consisted of orientations and fiber volume fractions as well as the cross-sectional size and shape of the reinforcement fibers. Glass fiber with CNT nanofillers in the composite could improve the fiber-matrix interfacial strength, which will enhance the adhesion and thus improve the composite delamination resistance. The GFs in this work were satin weave fabrics with 0 and 90 degree orientations since EMI could come from any direction in practical applications. The content of GFs was controlled by the number of plies during sample preparation. FIG. 4 (a) shows the relation between the weight percentage of GFs and the number of GF plies in the composites (in 2 mm thickness). As can be seen in FIG. 4 (a) The weight percentages of GFs in composites with different GF plies in the composites; (b) The density of the composites for various GF loadings; (c) Stress-strain curves; and (d) tensile strength (with error bar) of the composites with various GF loadings.

The mass densities of the composites were also impacted by the content of GFs, as shown in FIG. 4 (b), that were measured to be 1.55, 1.73, 1.88 g·cm⁻³ for 55, 67, 74 wt % GF reinforced composites, respectively. It is about 30%˜43% lighter than the commercial aluminum alloy 6061 which has a mass density of about 2.7 g·cm⁻³. The higher weight percentage of GFs in the composite leads to stronger reinforcement as shown in FIGS. 4 (c) and (d). The stress-strain measurements showed that the composite with 6 plies (55 wt %) of GFs obtained the average tensile strength of ˜313 MPa that was further increased to ˜361 MPa for the one with 8 plies (67 wt %) GFs. The average tensile strength of the composites with 10 plies (74 wt %) GF reinforcement was found to reach ˜427 MPa.

This is a dramatic improvement comparing to the neat CNT-epoxy composites (around 15 MPa) from our previous research. It has been known that the tensile strength in polymer composites highly dependent on the orientations of GFs. The tensile strength of the GF reinforced polymer composites (without CNTs) for the combination of 0- and 90-degree fiber orientations and 60 wt % GFs was reported as about 400 MPa, that is consistent with our data. The tensile tests for the composites with various MWCNT loadings were also performed as shown in Figure S1 in Supporting Information.

The GF content in the composites was maintained at 55 wt %. It was observed that the composites exhibited ultimate tensile strength of 290˜360 MPa with different contents of MWCNT nanofillers. Figure S1 (b) shows the tensile strength for MWCNT-GF-epoxy composites with various MWCNT loadings in column chart. The composites with 0.0, 0.4, and 1.4 wt % MWCNT loadings show similar tensile strength around 300 MPa, while the tensile strength of the composites with 2.3 and 3.1 wt % MWCNT loadings reach to about 350 MPa. As the loading of MWCNT increased to 5.0 wt %, the tensile strength of the composite decreased to ˜300 MPa. It can be understood that the relatively small loading of MWCNTs can provide good particle dispersion and strong interface adhesion in the composites for effective stress transfer. Large loadings of MWCNTs in the composites may disrupt matrix continuity in the composites that decreased tensile strength. Overall, it shows smaller impact of MWCNT loadings on the tensile strength than that of GFs. The tensile strength of the MWCNT-GF-epoxy composites is dominated by the contribution of the GF content, while the electromagnetic properties are highly impacted by MWCNTs and the interfaces between MWCNT nanofillers and GFs as discussed in the following sections.

### Electrical and Microwave Absorption Properties

### Electrical Conductivity of MWCNT-GF-Epoxy Composites

Epoxy and GFs are electric insulators, the electrical conductivity of MWCNT-GF-epoxy composites highly depends on the incorporation of MWCNTs in the composites. FIG. 5 shows the electrical conductivity of MWCNT-GF-epoxy composites as a function of MWCNT loadings. That is, FIG. 5 depicts exemplary DC conductivities of MWCNT-GF-epoxy composites with various MWCNT loadings. The inset plot represents the linear form of the power law.

It is shown that the incorporation of conductive MWCNTs substantially increases the conductivity of the composites. The electrical conductivity of the composites changed from about 6.6×10⁻¹² S·m⁻¹ for zero MWCNT loading to about 1.3×10⁻⁴ S·m⁻¹ for 5 wt % MWCNT loading in the composite, a change of about 8 orders of magnitude. It indicated a transition from an insulating state to a more conductive state in the composite, due to the formation of a conductive network throughout the insulating polymer matrix.

This property can be understood by the percolation theory for charge transport, which also involves effective electron tunneling or hopping. In percolation theory, when a conductive filler is dispersed in an insulating polymer, electrically conductive channels can be achieved when the filler concentration is high enough to form some conductive networks. The minimum filler loading where the first conductive network was formed within the polymer matrix is known as the percolation threshold. It can be calculated by plotting the electrical conductivity as a function of the filler content fraction and performing data fitting with a percolation power-law function:

σ_{c}∝(ϕ−ϕ_{c})^{t} (1)

where σ_{c} is the conductivity of the composites; ϕ is the filler fraction; ϕ_{c} is the filler fraction at the percolation threshold; and t is the power-law exponent. The inset plot in FIG. 5 represents a linear relationship of the above expression, obtained by applying logarithms to both sides of the equation. Herein, ϕ_{c}=2.3 wt % was observed for the MWCNT-GF-epoxy composite and the value of power-law exponent t was about 5.1.

Microwave Absorption Properties with Various MWCNT Loadings There are usually two main objectives for designing a microwave absorption material: reducing reflection and increasing absorption of incident EM wave over a broadband of frequencies. When an EM wave impinges on a material, it is possible to have partial reflection, absorption, and transmission. According to the analysis of measured S-parameters, reflectance (R), transmittance (T), and absorbance (A) can be calculated as R=|S₁₁|² or |S₂₂|², T=|S₁₂|² or |S₂₁|², and A=1−R−T.

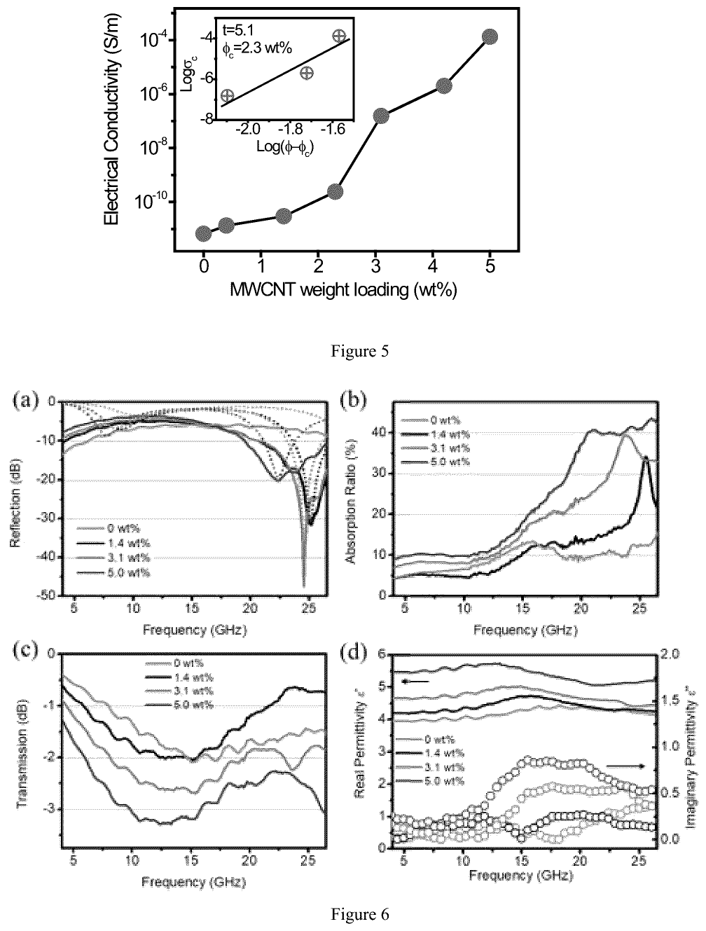

The EM wave reflection properties through air to an absorption material can be understood from the transmission line theory described in Supporting Information. Here, we first studied the MWCNTs loading effect on the microwave absorption properties of the MWCNT-GF-epoxy composites. FIG. 6 presents the microwave absorption properties of four composite samples with the MWCNT loadings of 0, 1.4, 3.1 and 5.0 wt % in the composites. The GF content in the composites was maintained at 55 wt % and the thickness of all samples was controlled as 3 mm.

As for multifunctional applications, the EM wave absorption properties of the composites can be enhanced by taking the advantage of large thickness of structural materials, that is different from coating, which has a limited thickness.

As discussed more fully below, FIG. 6 are exemplary depictions of (a) The microwave reflection loss (RL), (b) absorption ratio, (c) transmission loss (TL), and (d) permittivity value of MWCNT-GF-epoxy composites with different MWCNT loadings in wt %. Different from the previous presentation, we present here more comprehensive results of microwave absorption properties, including reflection loss, absorption ratio, transmission loss, and permittivity of the composites.

FIG. 6 (a) presents the microwave reflection properties of the MWCNT-GF-epoxy composites with various MWCNT loadings in wt % of the composites in the frequency range from 4-26.5 GHz. The dash lines present the calculated curve and the solid lines show the experimentally measured results of the RL. The calculated data were obtained from Equation (S3) and the input parameters for e and d are listed in Table S2 in the Supporting Information. There is a good agreement between the calculated data and the measurement results, especially the RL peak positions are nearly the same. A RL value below −10 dB corresponds to about 90% of EM wave reflection reduction and is regarded as effective for some applications.

The composites show higher microwave reflection for higher MWCNT loadings samples from about 4-17 GHz. This is due to the networks between the CNTs. For the composites without the loading of MWCNTs, the reflection is stable in the higher frequency range from about 17 to 26.5 GHz, while some reflection dips are shown for the composites with the loadings of MWCNTs (FIG. 6 (a)). The composites exhibited a strong reflection reduction in the high frequency range from 20.5 to 26.5 GHz, with strong reflection dips. The maximum RL (RL peak value) is −32 dB at 25.2 GHz for the composite with 1.4 wt % MWCNTs, and −48 dB at 24.5 GHz for 3.1 wt % MWCNTs. An effective RL bandwidth (i.e., the frequency range for RL below −10 dB) of ˜6 GHz can be obtained for the 1.4 wt % and 3.1 wt % MWCNT composites. When the MWCNT loading was increased to 5.0 wt % in the composites, the maximum RL was decreased to −20 dB at 22.4 GHz and the effective RL bandwidth reached to about 7.1 GHz (from 19.4 to 26.5 GHz). It was clearly shown that the RL peak shifted from higher frequency region to lower frequency region as the MWCNT loading was increased in the composites.

The composites can interact with EM microwave and absorb the wave energy that becomes heat through the interactions of EM field with the molecular and electronic structure of the materials. FIG. 6 (b) presents the microwave absorption ratio of the composites. The absorption ratio of the composites highly depends on the MWCNT loadings, especially in the high frequency range (15 to 26.5 GHz). For the epoxy-GF composite without MWCNTs, the absorption ratio is lower than 10% in most of the measured frequency regions. With 1.4 wt % MWCNT nanofillers in the sample, the absorption ratio was not much different from that of the sample without MWCNTs in the low frequency region (4-17 GHz); as the frequency increases, the absorption ratio increases to the maximum value of 34% at 25 GHz. As the MWCNT nanofillers in the composites increased to 3.1 wt %, the absorption ratio is about 8% between 4-10 GHz frequency range, and then gradually reaches to about 40% at 23 GHz.

The composite with 5.0 wt % MWCNTs exhibits an excellent EM wave absorption from 15 to 26.5 GHz, reaching to about 44% at 26 GHz. It is known that the external EM radiation can induce an induction current in the conductive networks due to the conductive charge transportation between different MWCNTs in the composites, which contributes to the improvement of EM absorption performance in the composites.

As the energy of an incident microwave radiation onto a material is partly reflected and absorbed, a transmission loss (TL) can also be achieved. FIG. 6 (c) illustrates the transmission (the minus in dB represents a transmission loss, also called EMI shielding effectiveness) of the composites with various loadings of MWCNT. As the MWCNT loading increases, the TL is also improved in the measured frequency range (4-26.5 GHz). Further, when the MWCNT loading in the composite increases to 5.0 wt %, the TL reaches to −3.3 dB at 13 GHz, which is about 53% transmission reduction. This is consistent with the result of FIG. 6 (b), owing to the strong EM wave absorption of the composite in the corresponding frequency band.

The complex permittivity of the MWCNT-GF-epoxy composites were calculated by using the Agilent 85071E Materials Measurement Software (which is an integral part of the Agilent Network Analyzer N5230C PNA-L) and the experimental data of measured S-parameters. FIG. 6 (d) presents the real (ε′) and imaginary (ε″) parts of the complex permittivity of the composites with various MWCNT loadings in the frequency range (4-26.5 GHz). All the composites have different conductivity, dielectric constant, and different interfacial interactions which results in different permittivity values. Both of the ε′ and ε″ values increase with the increased MWCNT contents. As the loading of MWCNT increases from 0 to 1.4 wt %, the ε′ of the composites slowly increases from ˜3.9 to ˜4.3 over the entire measurement frequency range. Since the average inter-particle distance in the composite is large for low MWCNT loading, the localized charges in the particles result in induced interfacial polarization due to the incident EM wave, however, that will not result in a long range charge movement. Further increasing the MWCNT loadings to 3.1 wt % and then to 5.0 wt % in the composites, the ε′ increases at a faster rate and reaches to about ˜4.8 and ˜5.5, respectively.

It also shows frequency dependence for these composites. The increment of ε′ with the increased MWCNT loading is attributed to the interfacial Maxwell-Wagner polarization effect between the epoxy and MWCNTs which have high dielectric constant^{[49]}. The ε″ of the composites also increased from ˜0.1 to ˜0.8 in the measured frequency range from 10 to 22 GHz for the MWCNT loading increased from 0 to 5.0 wt % with some frequency dependence. The E can be approximated as

$${ε}^{″} = {ε}_{p}^{″} + \frac{{σ}_{dc}}{{ε}_{0} ω} \qquad ( 2 )$$

where ε′ₚ represents the polarization loss; and σ_{dc} is the DC conductivity^{[50}]. The total dielectric loss can be attributed to conduction loss and polarization loss. Therefore, as the conductivity of the composite enhanced for the increased MWCNT loading (see FIG. 5), the ε″ values also increase for the corresponding composite.

### Microwave Absorption Properties of MWCNT-GF-Epoxy Composites with Various GFs and MWCNTs

GF reinforced polymers have been widely used in industries. They can improve not only the stiffness, toughness, hardness, heat distortion temperature, and mold shrinkage, but also reduces the processing cost significantly. The composite materials may present some advantage with the high qualities of their components or constituents and sometimes they can have some qualities that the constituents may not possess, due to the significance of the large number of interfaces in the composite materials.

In this work, the type of GF used is E-glass fiber, which contains alumino-borosilicate glass with less than 1 wt % alkali oxides. Due to the weak electrical and magnetic characteristics of both epoxy resin and GF, the GF reinforced epoxy composites without MWCNT do not exhibit much microwave absorption. As shown in Figure S2, the microwave absorption ratio for the composites with different GF loadings without MWCNT were below 8% in the low frequency region (4-12 GHz). Meanwhile, the reflection and transmission of the samples without MWCNT also do not present much interesting feature and therefore did not include here.

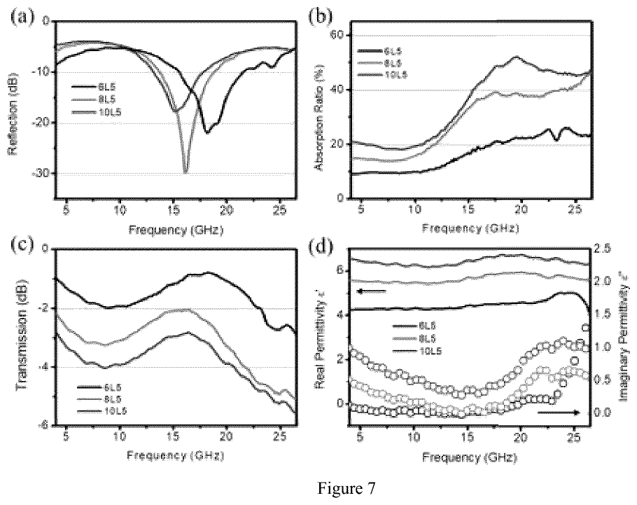

In Figure S2, the samples notations 6L0, 8L0, and 10L0 refer to 6, 8 and 10 layers of GFs in the composites in 2 mm without MWCNT loadings, which correspond to 55 wt %, 67 wt %, and 74 wt % of GFs in the composites. All the samples in Figure S2 have a thickness of 4 mm. In the high frequency region (13-25 GHz), the microwave absorption ratio of the composite samples shows more complex frequency dependencies. As the GF loadings increased from 0 to 55 and 67 wt % and then to 74 wt %, the complexity of the frequency dependence of the microwave absorption ratio became much more pronounced, which were attributed to the high density interfaces between GF and epoxy matrix, especially for high GF loading such as 74 wt % GFs in the composite. Hence, we further systematically studied the microwave absorption properties of the composites as a function of the GF and MWCNT loadings. FIG. 7 shows the microwave absorption properties of the composites 6L5, 8L5, and 10L5, with different GF and MWCNT loadings. All the samples in FIG. 7 also have the thickness of 4 mm. As discussed more fully below, FIG. 7 depicts exemplary (a) The microwave reflection loss, (b) absorption ratio, (c) transmission loss, and (d) permittivity value of MWCNT-GF-epoxy composites with different GF contents and 5 wt % MWCNTs in epoxy resin, according to various embodiments of the invention.

Here, the notations 6L5, 8L5, and 10L5 refer to the composites included 6, 8 and 10 layers of satin weave fabrics 7781E in 2 mm, respectively, and the MWCNT loading in the CNT-epoxy solution was controlled as 5 wt %. It should be noted that the final MWCNT contents in the MWCNT-GF-epoxy composites are highly influenced by the GF contents. As the GF contents increased in the composites, the MWCNT contents in the final composites were decreased. The final GF loadings in 6L5, 8L5, and 10L5 composites were 55 wt %, 67 wt %, and 75 wt %, respectively. Whereas the final MWCNT contents in 6L5, 8L5, and 10L5 were 2.3 wt %, 1.5 wt % and 1.1 wt %, respectively.

As shown in FIG. 7(a), these composites show strong reflection dips (or RL peaks) in the middle frequency region. The maximum RL for 6L5, 8L5, and 10L5 samples reached to −22 dB at 18.2 GHz, −30 dB at 16.2 GHz, and −18 dB at 15.1 GHz, respectively. The effective RL bandwidths of these composites were listed in Table S3 in the Supporting Information. FIG. 7 (b) shows the microwave absorption ratio of the composites. Interestingly, the strong microwave absorptance (or absorption ratio) in the entire measured frequency range was observed for the composite with higher GF content and reduced MWCNT loading. The 6L5 composite, which contains 2.3 wt % MWCNTs and 55 wt % GFs in final composite, produced an absorption ratio about 10% in frequency range of 4-12 GHz, and reaches to about 23% in the frequency region of 20-26.5 GHz. For the 8L5 composite sample with 1.5 wt % MWCNTs and 67 wt % GFs, the absorption ratio shows a strong frequency dependence. The absorption ratio is about 15% in the frequency range of 4-10 GHz, gradually increases to about 40% at 17 GHz and reaches to a maximum of 46% at 26.5 GHz. While the GF content increased to 75 wt % for 10L5 composite with 1.1 wt % MWCNTs, the absorption ratio starts from about 20% in the frequency range of 4-11 GHz, increases to about 53% at 20 GHz. Since GF and epoxy are electric insulators and have weak electromagnetic characteristics, they contribute weakly to microwave absorption as shown in Figure S2. Previous research results showed that MWCNTs are electrically conductive and contributed strongly to microwave absorption in polymer composites. Nevertheless, the results of FIG. 7 (b) showed the physical feature or trend contradicting to the conventional wisdom.

The understanding of such results pointed to that the high-density interfaces between MWCNT-epoxy and GFs may also play an important role for the microwave absorption properties of the composites, especially for the samples with relatively high GF and MWCNT loadings as shown in FIG. 3. In those composites, MWCNT-epoxy matrices possess relatively high electric conductivity (as shown in FIG. 5) and high permittivity (ε′ and ε″) values (as shown in FIG. 6(d)) that lead to relatively high values of refraction index in the matrices; however, GFs are electric insulator and possess relatively low permittivity and refraction index. Once microwave signal transmitted into GFs and can then be nearly trapped in the GFs, an effect similar to that in optical fibers, due to the large EM wave reflection to GFs at the interfaces between GFs and MWCNT-epoxy matrices. Such effect could lead to multiple scatterings and multiple absorptions of EM wave in the sample, which can increase the microwave absorption in the composites. The interactions at MWCNT-epoxy and GF interfaces can also influence the electrical polarization at the interfaces in the composites, which consequently affect the microwave absorption properties.

The TL in FIG. 7 (c) synchronizes with the microwave absorption ratio as in FIG. 7 (b). The 6L5 composite has the TL value lower than −2 dB (about 37%) in most of the measured frequency range with a frequency dependence. Both 8L5 and 10L5 have the TL value between −2 dB and −4 dB (about 60%) in the frequency range of 4-21 GHz, reaches to −5 dB (about 68%) at 26.5 GHz for 8L5 and −5.5 dB (about 72%) for 10L5 composites. The TL in 8L5 and 10L5 is better than that of 6L5, because of the higher microwave absorption in 8L5 and 10L5 than 6L5.

FIG. 7 (d) shows the real (top) and imaginary (bottom) parts of dielectric permittivity of the composites. The high microwave absorption can be achieved with high dielectric constant and loss, while the dielectric loss ability mainly comes from conductivity loss and polarization loss. The real permittivity of 6L5, 8L5, and 10L5 are around 4.6, 5.6, and 6.5, respectively. The imaginary permittivity is lower than 1.0 for all these samples and increases as the GF contents increase. The shapes and sizes of the MWCNT fillers in the composites mainly impact the dielectric loss due to percolation process.

Further, we increased the MWCNT loading in the epoxy resin to 7 wt % and used the MWCNT-epoxy solution to repeat the fabrication of the composites with various GF loadings. Figure S3 (a) shows the EM reflection properties of the composites. The sample thicknesses are also 4 mm. The convention of the sample notations remains the same as discussed above for Figure S3. The final GF loadings in 6L7, 8L7, and 10L7 composites were 55 wt %, 66 wt %, and 74 wt %, respectively. Whereas the final MWCNT contents in 6L7, 8L7, and 10L7 were 3.1 wt %, 2.3 wt % and 1.7 wt %, respectively. The maximum RL values of 6L7, 8L7, and 10L7 are −26 dB at 18 GHz, −17 dB at 15.4 GHz, and −15 dB at 13.8 GHz, respectively. The RL peaks shifted to lower frequencies, in comparison to that of the samples with 5 wt % MWCNTs in epoxy resin as shown in FIG. 7 (a).

Figure S3 (b) presents the microwave absorption ratio of 6L7, 8L7, and 10L7 samples. As shown in Figure S3 (b), the composite samples 8L7 and 10L7, which possess higher GF loadings and reduced MWCNT contents, also present stronger microwave absorptances in the measured frequency range than that of 6L7 sample, which has relatively lower GF loading and higher MWCNT content. Though, such peculiar trend contradicts to the conventional wisdom, but is consistent with the results of FIG. 7 (b). As discussed above, MWCNTs and high density interfaces in the composites provide the material with its high microwave absorption ability due to the MWCNT's dielectric relaxation and the differences of the dielectric properties MWCNTs with GFs. For 8L7 and 10L7 composites, the absorption ratios reach to the maximum 48% at 17.5 GHz and 59% at 26.5 GHz, respectively.

The TL of 8L7 in Figure S3 (c) can reach to the maximum about −5.2 dB (about 70%) at 25 GHz, while 10L7 composite shows a maximum TL of about −5.5 dB (about 72%) at 21 GHz. The analogical microwave absorption properties of 8L7 and 10L7 could be caused by the similar dielectric permittivity as shown in FIG. 6 (d). As mentioned above, MWCNTs and complex interface polarizations in the composites provide the material with most of its microwave absorption ability due to the MWCNT's dielectric relaxation. Both real and imaginary permittivity of 8L7 and 10L7 are higher than 6L7 as shown in Figure S3 (d), meaning higher energy storage capability and loss networks were formed in high content GF composites.

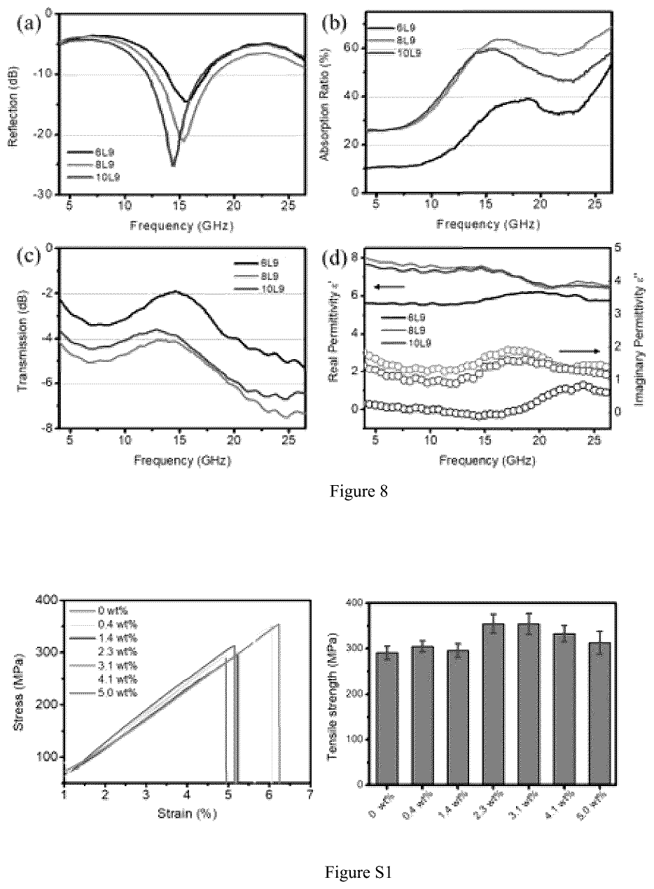

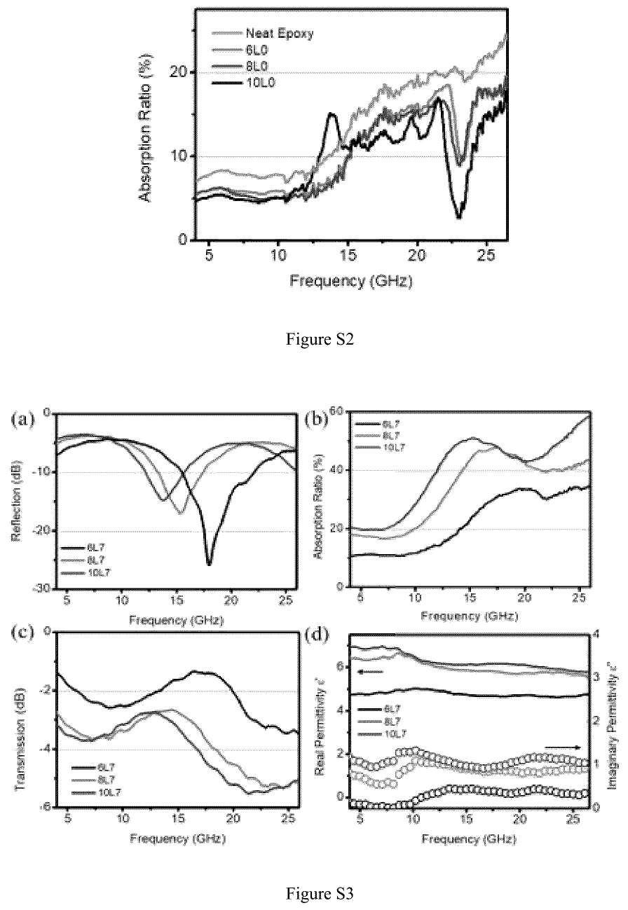

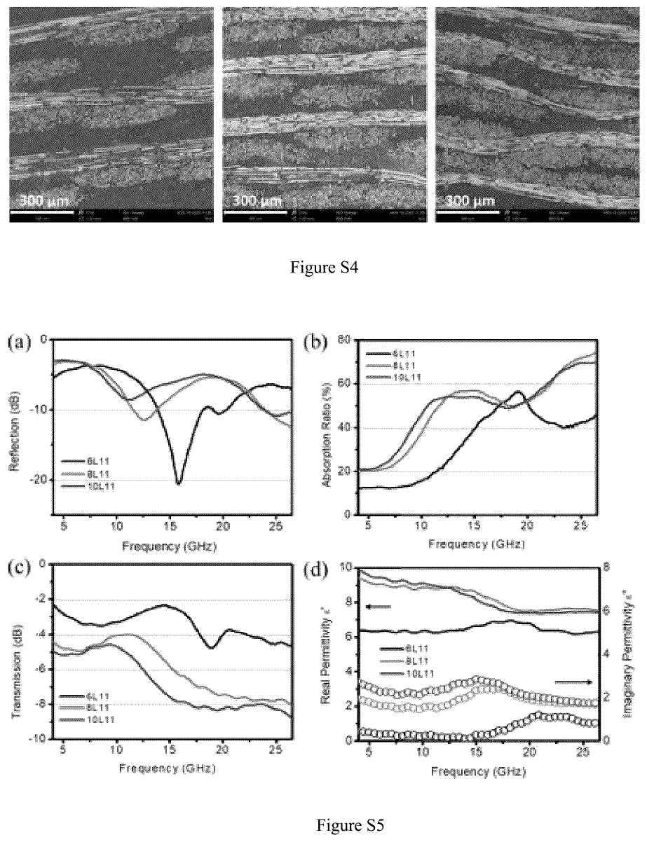

As the next step, we further increased the MWCNT loading in the CNT-epoxy resin to 9 wt % and repeated the fabrication process for the composites with various GF loadings. FIG. 8 shows the microwave absorption properties of these MWCNT-GF-epoxy composites with different GF contents. As discussed more fully below, FIG. 8 depicts (a) The microwave reflection loss, (b) absorption ratio, (c) transmission loss, and (d) permittivity value of MWCNT-GF-epoxy composites with different GF contents and 9 wt % MWCNTs in epoxy resin, according to various embodiments of the invention.

In this series, the final MWCNT contents in 6L9, 8L9, and 10L9 were 4.1 wt %, 3.1 wt % and 2.4 wt %, respectively. The sample thicknesses are 4 mm. FIG. 8 (a) shows that these composites present strong RL peaks in the middle of the measured frequency region. The maximum RL for 6L9, 8L9, and 10L9 are −14 dB at 15.6 GHz, −21 dB at 15.2 GHz, and −25 dB at 14.5 GHz, respectively. Other RL data of the samples are summarized in Table S3 in the Supporting Information.

FIG. 8 (b) presents the microwave absorption ratio of the composites. Both 8L9 and 10L9 samples show strong microwave absorption in the frequency region 12-26 GHz. It is interesting to note that the absorption ratio of 8L9 is even higher than that of 10L9 in the frequency region 15-26.5 GHz, reaching to above 60% in the frequency region 14.5-19.5 GHz and 24-26.5 GHz.

Comparing with the results of FIGS. 7 (b) and 8 (b), as the loading of MWCNT fillers increased, the microwave absorptance in the composites is enhanced (see FIG. 8 (b)). This is consistent with the results in FIG. 6 since relatively higher loading of MWCNT fillers can enhance the constitutions of the conductive networks, which will strengthen the dielectric loss and raise the microwave absorption capability of the composites.

FIG. 8 (c) presents the microwave transmission properties of the composites. The TL of 8L9 is better than both 6L9 and 10L9 in the entire measured frequency range, reaching to about −6 to −7.5 dB in the frequency region 20-26.5 GHz (corresponding to 75% and 82% in shielding effectiveness). FIG. 8 (d) shows the values of the real and imaginary parts of permittivity of the composites with different GF contents. In this group of composites, the real part of permittivity of 8L9 and 10L9 are quite similar while the imaginary part of permittivity of 8L9 is slightly higher than that of 10L9. It is believed that the homogenous distribution of MWCNT/GF interfaces in the matrix could improve the microwave absorption performance of the composites. Figure S4 shows the cross-section SEM images of 6L9, 8L9, and 10L9 composites. It is clearly seen that some GFs in 10L9 are deformed, while the distribution of GFs in 8L9 is more orderly and regularly. The high density of interfaces between MWCNTs-epoxy matrices and GFs can also be seen from Figure S4. In our composite experiments, the highest MWCNT loading in epoxy resin can be achieved to 11 wt %. Higher than 11 wt % MWCNTs loading, we cannot obtain a homogeneous CNT-epoxy solution because its viscosity became too high. So, we used the 11 wt % MWCNT-epoxy solution to fabricate the composites (named as 6L11, 8L11, and 10L11) in the test.

The microwave absorption properties of the composites are presented in Figure S5 in Supporting Information. Sample 6L11 still showed a strong RL peak and the maximum RL reached to −20.5 dB at 15.8 GHz. However, the RL values of 8L11 and 10L11 composites as shown in Figure S5 (a) were less favorable than that of 8L9 and 10L9 as in FIG. 8 (a). There are two reasons for such results: (1) the relationship between reflection loss and surface roughness, since the composites with high loading of MWCNTs and GFs have the highest surface roughness, due to the MWCNT agglomerations and high viscosity of the MWCNT-epoxy solution; and (2) the growing impedance mismatch caused by the high loading of conductive MWCNTs. Figure S5 (b) shows that the microwave absorption ratio and frequency dependence of 8L11 resemble to that of 10L11. It starts at 20% in the low frequency region (4-6 GHz) and increases up to about 70% at 26.5 GHz. The absorption ratio of these two samples 8L11 and 10L11 did not show much improvement comparing to that of 8L9 and 10L9 (FIG. 8 (b)). Figure S5 (c) exhibits the TL of the composites. The 10L11 composite achieved good TL, reaching to −8 dB (about 84%) in a wide bandwidth from 17 to 26.5 GHz, validating the effectiveness of the MWCNT/GF interfaces for microwave absorption.

The microwave absorption properties of the MWCNT-GF-epoxy composites in the current work were compared with the results from some other published papers on various CNTs based polymer composites, as shown in Table 1. Most of the previous studies presented some good results on RL, TL, or absorption ratio for their composites, but rarely reporting results on all the three quantities in the same studies. Here we presented the results on all the three quantities, i.e., RL, TL, and absorption ratio, in the current studies for the composites for better understanding of their microwave absorption properties. Figure S5 (d) presents the real and imaginary parts of the permittivity of the composites. The samples of 8L11 and 10L11 show quite high ε′ values, from about 9.5 in low frequency region to about 6 in the high frequency region. The average value of ε″ for 10L11 is also quite high, reaching to the highest among all the composites in the experiment since it has the highest MWCNT loading as well as the highest GFs in the composites.

### CONCLUSIONS

In this work, various MWCNT-GF-epoxy composites with different MWCNT loadings and GF reinforcement were fabricated and studied. We systematically investigated the microwave absorption property dependence on the loadings of MWCNTs and GFs in MWCNT-GF-epoxy composites. With MWCNTs and GFs loadings, the composites exhibit prominent EM wave absorption properties and high reflection loss at distinct frequency ranges. The EM wave absorption ratio as well as the transmission loss were much improved with the increased MWCNT and GF loadings. Moreover, with relatively high loadings of MWCNTs and GFs, the composites showed some peculiar microwave absorption property dependence, due to the high-density interfaces in the MWCNT-GF-epoxy composites. The tensile strength of the composite is much enhanced due to the GF reinforcement, which is comparable to commercial aluminum alloy, but with much lower mass density. With 74 wt % GF contents, the tensile strength of the composite can reach ˜427 MPa and the density is only 1.88 g·cm⁻³. The results show that the MWCNT-GF-epoxy composites may have the potential for structural and microwave absorption applications without the need of additional coating.

### S1. Transmission Line Theory

It should be noted that the transmission line theory provides a basis for the electromagnetic (EM) wave reflection properties through air to an absorption material can be understood from the transmission line theory.

The reflection loss (RL) of normal incident EM wave at the absorber surface is given by [1],

$$RL = 20 log \vert Γ \vert = 20 log \vert \frac{{z}_{n} - {z}_{0}}{{z}_{n} + {z}_{n}} \vert \qquad ( S1 )$$

where Γ is the reflection coefficient, Zₙ is the wave impedance of the material, and Z₀ is the wave impedance of air. For a single layer of homogenous material, the RL can be written as,

$$RL = 20 log \vert Γ \vert = 20 log \vert \frac{\sqrt{\frac{μ}{ε}} tanh ( j \frac{2 π fd}{v} \sqrt{με} ) - 1}{\sqrt{\frac{μ}{ε}} tanh ( j \frac{2 π fd}{c} \sqrt{με} ) + 1} \vert \qquad ( S2 )$$

where μ and ε are the relative complex permeability and permittivity of the material, respectively; d, f, and c denote the sample thickness, frequency, and speed of light. Since the MWCNT-GF-epoxy composites can be considered as dielectric absorbent due to the weak magnetic characteristics of GF, epoxy resin, and MWCNTs, the permeability μ≈−j0, the equation can then be written as,

$$RL = 20 log \vert Γ \vert = 20 log \vert \frac{\sqrt{\frac{1}{ε}} tanh ( j \frac{2 π fd}{c} \sqrt{ε} ) - 1}{\sqrt{\frac{1}{ε}} tanh ( j \frac{2 π fd}{c} \sqrt{ε} ) + 1} \vert \qquad ( S3 )$$

According to Equation (S3), when an EM wave was transmitted through an MWCNT-GF-epoxy composite, its RL properties mostly depend on the permittivity e, sample thickness d, and the wave frequency f. When an external EM wave exposes to the materials, two types of electric current will be induced from the radiation. The real part of the permittivity ε′ is mainly contributed from the displacement current, which represents the ability of energy storage from an external EM field. The conduction current due to the presence of free electrons leads to the major contribution to the imaginary part of the permittivity, ε″, which represents the ability of energy dissipation.

TABLE 1
Comparisons of some microwave absorption properties of present work with
different CNT polymer composites from some previous publications.

| | | RL > 10 dB | Maximum | Maximum |
|---|---|---|---|---|
| CNTs based Polymer | Thickness | bandwidth | Absorption | Transmission |
| Composites | d (mm) | (GHz) | Ratio | Loss (dB) |
| PANI/CNTs | 2.0 | 6 | — | — |
| Epoxy/MWCNTs | 3.0 | — | 65% | −10 |
| PANI/4CNTs | 2.4 | 4.6 | — | — |
| PVDF/ABS/GO/MWCNTs | 2.0 | 2.8 | — | — |
| PBO/Graphene/MWCNTs | 2.6 | 4.2 | — | — |
| PS@SiO₂/MWCNTs | 2.5 | 4.8 | — | — |
| PVDF/MWCNTs | 1.7 | 8.5 | — | — |
| TPU/MWCNTs | 3.0 | 3.3 | — | — |
| Epoxy-GF-MWCNTs | 4 | 6.1 | 70% | −8 |

TABLE S1
MWCNT-epoxy-GF composites with various
GF contents and MWCNT loadings.

| | | | MWCNT wt % in | |
|---|---|---|---|---|
| Sample | # plies of | | epoxy resin & | MWCNT wt % in |
| IDs | GFs in 2 mm | GF (wt %) | hardener | final composites |
| 6L0 | 6 | 55% | 0% | 0.0% |
| 6L1 | 6 | 56% | 1% | 0.4% |
| 6L3 | 6 | 55% | 3% | 1.4% |
| 6L5 | 6 | 55% | 5% | 2.3% |
| 6L7 | 6 | 55% | 7% | 3.1% |
| 6L9 | 6 | 53% | 9% | 4.1% |
| 6L11 | 6 | 54% | 11% | 5.0% |
| 8L5 | 8 | 67% | 5% | 1.5% |
| 8L7 | 8 | 66% | 7% | 2.3% |
| 8L9 | 8 | 67% | 9% | 3.1% |
| 8L11 | 8 | 65% | 11% | 4.1% |
| 10L5 | 10 | 75% | 5% | 1.1% |
| 10L7 | 10 | 74% | 7% | 1.7% |
| 10L9 | 10 | 73% | 9% | 2.4% |
| 10L11 | 10 | 73% | 11% | 3.1% |

TABLE S2
Calculated and experimental permittivity of
the composites with various MWCNT loadings.

| MWCNTs in | | Calculated | Calculated | Experimental | Experimental | Thickness |
|---|---|---|---|---|---|---|
| composites | | ∈′ | ∈″ | ε′ at RLₘₐₓ | ε″ at RLₘₐₓ | d (mm) |
| 0 | wt % | 4.9 | 0.4 | 3.9 | 0.12 | 3 |
| 1.4 | wt % | 5.8 | 1.1 | 4.0 | 0.16 | 3 |
| 3.1 | wt % | 6.9 | 1.2 | 4.5 | 0.41 | 3 |
| 5.0 | wt % | 8.3 | 1.6 | 5.1 | 0.85 | 3 |

TABLE S3
Reflection loss and dielectric permittivity
of MWCNT-GF-epoxy composites.

| | | RL peak | | |
|---|---|---|---|---|
| Sample | RL < −10 dB | position/ | Average | Average |
| IDs | bandwidth (GHz) | Freq. (GHz) | ε′ | ε″ |
| 6L5 | 6.1 | 18.1 | 4.3 | 0.1 |
| 8L5 | 5.2 | 16.2 | 5.6 | 0.3 |
| 10L5 | 4.7 | 15.2 | 6.3 | 0.7 |
| 6L7 | 5.6 | 18 | 4.8 | 0.4 |
| 8L7 | 4.1 | 15.4 | 5.9 | 0.8 |
| 10L7 | 3.5 | 13.8 | 6.5 | 1.2 |
| 6L9 | 3.6 | 15.6 | 5.8 | 0.4 |
| 8L9 | 5.4 | 15.2 | 7.2 | 1.2 |
| 10L9 | 5.1 | 14.5 | 7.1 | 1.6 |
| 6L11 | 4.4 | 15.8 | 6.5 | 0.6 |
| 8L11 | 2.2 | 12.5 | 8.4 | 1.9 |
| 10L11 | 0 | N/A | 8.3 | 2.7 |

We claim:

1. A process for forming multifunctional carbon nanotubes-glass fiber-epoxy composites with high density interfaces for microwave absorption and structural materials applications, comprising:
a. loading an epoxy resin with multi-walled carbon nanotube (MWCNT) to create a MWCNT-epoxy resin solution;
b. stirring the MWCNT-epoxy resin solution to avoid agglomeration to produce a stirred MWCNT-epoxy resin solution;
c. pouring a hardener into the MWCNT-epoxy solution;
d. mixing the MWCNT-epoxy resin solution including the hardener for a predetermined time to produce a mixed and stirred MWCNT-epoxy resin solution;
e. laying up the mixed and stirred MWCNT-epoxy resin solution into a steel mold, wherein the steel mold contains multiple layers of GF to produce a MWCNT-epoxy resin solution and GF;
f. curing the MWCNT-epoxy resin solution and GF in the steel mold to produce a cured MWCNT-epoxy resin solution and GF; and
g. post curing the cured MWCNT-epoxy resin solution and GF for a predetermined time and temperature.

2. Process for forming the composite of claim 1, wherein
a. loading the epoxy resin includes loading the epoxy resin with 5 wt % MWCNT to create the MWCNT-epoxy resin solution, wherein the MWCNT comprises a >95% purity with wall outer diameter <8 nm and lengths between 10-30 μm;
b. stirring the MWCNT-epoxy resin solution comprises stirring the MWCNT-epoxy solution for about 17 hours using shear-mixing method with an overhead stirrer at the speed of 100 revolutions per minute (rpm);
c. mixing the MWCNT-epoxy resin solution including the hardener comprises mixing the MWCNT-epoxy resin solution including the hardener for 15 minutes;
d. curing the MWCNT-epoxy resin solution and GF in the steel mold includes curing the MWCNT-epoxy resin solution and GF in the steel mold for 24 hours at 50° C.; and
e. post curing the cured MWCNT-epoxy resin solution including the GFs includes post curing the cured MWCNT-epoxy resin solution including the GFs for 48 hours at 80° C.

3. A process for forming the composite of claim 2, wherein the GF is a satin weave GF fabric with fiber orientations at 0°/90°.

4. A process for forming the composite of claim 2, wherein the multiple layers of the GF comprise 6 layers of satin weave GF fabric.

5. A process for forming the composite of claim 4, wherein laying up the MWCNT-epoxy resin solution and GF results in GF loading at 55 wt % and a MWCNT at 2.3 wt %.

6. A process for forming the composite of claim 2, wherein the multiple layers of the GF comprise 8 layers of satin weave GF fabric.

7. A process for forming the composite of claim 6, wherein laying up the MWCNT-epoxy resin solution and GF results in GF loading at 67 wt % and a MWCNT at 1.5 wt %.

8. A process for forming the composite of claim 2, wherein the multiple layers of the GF comprise 10 layers of satin weave GF fabric.

9. A process for forming the composite of claim 8, wherein laying up the MWCNT-epoxy resin solution and GF results in GF loading at 75 wt % and a MWCNT at 1.1 wt %.

10. Process for composite of claim 1, wherein:
a. loading the epoxy resin includes loading the epoxy resin with 7 wt % MWCNT to create a MWCNT-epoxy resin solution, wherein the MWCNT comprises a >95% purity with wall outer diameter <8 nm and lengths between 10-30 μm;
b. stirring the MWCNT-epoxy resin solution includes stirring the MWCNT-epoxy solution for about 17 hours using shear-mixing method with an overhead stirrer at the speed of 100 revolutions per minute (rpm);
c. mixing the stirred MWCNT-epoxy resin including the hardener solution includes mixing the stirred MWCNT-epoxy resin solution for 15 minutes;
d. laying up the mixed MWCNT-epoxy resin solution and GF into a steel mold includes laying up the mixed MWCNT-epoxy resin solution and GF into a steel mold, wherein the mold contains 6 layers of GF;
e. curing the mixed MWCNT-epoxy resin solution and GF in the steel mold includes curing the mixed MWCNT-epoxy resin solution and GF in the steel mold for 24 hours at 50° C.; and
f. post curing the cured mixed MWCNT-epoxy resin solution and GF includes post curing the cured mixed MWCNT-epoxy resin solution and GF for 48 hours at 80° C.

11. A process for forming the composite of claim 10, wherein the GF is a satin weave GF fabric with fiber orientations at 0°/90°.

12. A process for forming the composite of claim 11, wherein laying up the MWCNT-epoxy resin solution and GF results in GF loading at 55 wt % and a MWCNT at 2.3 wt %.

13. Process for forming the composite of claim 1, wherein:
a. loading the epoxy resin includes loading the epoxy resin with 9 wt % MWCNT to create a MWCNT-epoxy resin solution, wherein the MWCNT comprises a >95% purity with wall outer diameter <8 nm and lengths between 10-30 μm;
b. stirring the MWCNT-epoxy resin solution includes stirring the MWCNT-epoxy solution for about 17 hours using shear-mixing method with an overhead stirrer at the speed of 100 revolutions per minute (rpm);
c. mixing the MWCNT-epoxy resin solution including the hardener includes mixing the MWCNT-epoxy resin solution including the hardener for 15 minutes;
d. laying up the mixed and stirred MWCNT-epoxy resin solution into a steel mold includes laying up the mixed and stirred MWCNT-epoxy resin solution into a steel mold, wherein the mold contains 8 layers of GF;
e. curing the mixed and stirred MWCNT-epoxy resin solution and GF in the steel mold includes curing the mixed and stirred MWCNT-epoxy resin solution and GF in the steel mold for 24 hours at 50° C.; and
f. post curing the cured MWCNT-epoxy resin solution and GF includes post curing the cured MWCNT-epoxy resin solution and GF includes post curing the cured MWCNT-epoxy resin solution and the GF for 48 hours at 80° C.

14. A process for forming the composite of claim 13, wherein the GF is a satin weave GF fabric with fiber orientations at 0°/90°.

15. A process for forming the composite of claim 14, wherein laying up the mixed and stirred MWCNT-epoxy resin solution and GF results in GF loading at 67 wt % and a MWCNT at 1.5 wt %.

16. Process for forming the composite of claim 1, wherein:
a. loading an epoxy resin includes loading an epoxy resin with 11 wt % MWCNT to create the MWCNT-epoxy resin solution, wherein the MWCNT comprises a >95% purity with wall outer diameter <8 nm and lengths between 10-30 μm;
b. stirring the MWCNT-epoxy resin solution includes stirring the MWCNT-epoxy solution for about 17 hours using shear-mixing method with an overhead stirrer at the speed of 100 revolutions per minute (rpm);
c. mixing the stirred MWCNT-epoxy resin solution including the hardener includes mixing the stirred MWCNT-epoxy resin solution including the hardener for 15 minutes;
d. laying up the mixed and stirred MWCNT-epoxy resin into a steel mold, wherein the mold contains 10 layers of GF;
e. curing the mixed and stirred MWCNT-epoxy resin solution including GF in the steel mold includes curing the mixed and stirred MWCNT-epoxy resin solution including GF in the steel mold for 24 hours at 50° C.; and
f. post curing the cured MWCNT-epoxy resin solution and GF includes post curing the cured MWCNT-epoxy resin solution and GF for 48 hours at 80° C.

17. A process for forming the composite of claim 16, wherein the GF is a satin weave GF fabric with fiber orientations at 0°/90°.

18. A process for forming the composite of claim 17, wherein the MWCNT-epoxy resin solution including GF results in GF loading at 75 wt % and a MWCNT at 1.1 wt %.
